(19) United States
(12) Patent Application Publication
(10) Pub. No.: US 2026/0161293 A1
(43) Pub. Date: Jun. 11, 2026

(54) SYSTEMS AND METHODS FOR NON-TARGET RANK REFRESH OPERATION IN MULTI-RANK MEMORY SYSTEM

(71) Applicant: Micron Technology, Inc., Boise, ID (US)

(72) Inventors: Gary Howe, Allen, TX (US); Sujeet Ayyapureddi, Boise, ID (US); Clark Lu, Boise, ID (US)

(73) Assignee: Micron Technology, Inc., Boise, ID (US)

(21) Appl. No.: 18/977,543

(22) Filed: Dec. 11, 2024

(51) Int. Cl. G06F 3/06; G11C 11/406

(52) U.S. Cl. CPC G06F 3/0613; G06F 3/0659; G06F 3/0673; G11C 11/406

(57) ABSTRACT

Systems, apparatuses, and methods for a non-target refresh operation in a multi-rank memory system are disclosed. A command is received by a first memory rank and a second memory rank. The first memory rank may be a target rank, and the second memory rank may be a non-target rank. The first memory rank performs a first operation responsive to the command, and the second memory rank performs a second operation different from the first operation responsive to the command, the second operation comprising a refresh operation. In some embodiments, the first memory rank receives an active pulse of a first chip select signal for the command and the second memory rank receives at least two active pulses of a second chip select signal for the command. In some embodiments, the command includes at least one rank encoding bit to specify a target rank. The command may be an activate command.

### BACKGROUND

This disclosure relates generally to semiconductor devices, and more specifically to semiconductor memory devices. Disclosed embodiments relate to volatile memory, such as dynamic random-access memory (DRAM). A memory system (e.g., a memory module) may comprise a memory controller and multiple memory ranks. The memory controller may provide a command to cause a target rank of the multiple memory ranks to perform an operation, such as an access operation.

### BRIEF DESCRIPTION OF THE DRAWINGS

FIG. 1A is a block diagram illustrating a system according to embodiments of the disclosure.

FIG. 1B is a block diagram illustrating a system according to embodiments of the disclosure.

FIG. 2 is a block diagram illustrating a memory device according to embodiments of the disclosure.

FIG. 3 is a diagram illustrating an activate command according to embodiments of the disclosure.

FIG. 4 is a diagram illustrating an activate command according to embodiments of the disclosure.

FIG. 5 is a flow diagram illustrating a process for an operation performed by a memory device responsive to a command according to embodiments of the disclosure.

FIG. 6 is a flow diagram illustrating a process for operations performed by memory ranks responsive to a command according to embodiments of the disclosure.

FIG. 7 is a flow diagram illustrating a process for operations performed by memory ranks responsive to a command according to embodiments of the disclosure.

### DETAILED DESCRIPTION

The present disclosure provides descriptions of non-limiting example embodiments and is in no way intended to limit the scope of the disclosure or its applications or uses. In the following detailed description of embodiments of the present technology, reference is made to the accompanying drawings, which form a part hereof and in which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art, so as not to obscure the description of embodiments of the disclosure. The following detailed description is therefore not to be taken as limiting, and the scope of the disclosure is defined only by the appended claims.

A memory device includes a memory array. The memory array includes memory cells at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks. Information in a memory array may be accessed by performing access operations, such as read or write operations. During an example access operation, a word line may be activated responsive to an activate command based on a row address. Selected memory cells along that active word line may have their information read from, or written to, based on which bit lines are selected by a column address. The bit lines are coupled to sense amplifiers. The sense amplifiers sense a voltage on the bit line from the memory cells along the active word line and amplify it into a signal in a read operation or drive a voltage to the memory cell along the active word line in a write operation.

Memories and/or memory systems may be organized into ranks, such that one or more operations are performed by a target rank, while the one or more operations are not performed by one or more non-target ranks for the command. For example, one or more first memory devices in a memory system (e.g., a memory module) may be included in a first rank, and one or more second memory devices in the memory system may be included in a second rank. During operations, a memory controller may direct commands to one or more target memory ranks while non-target memory ranks remain idle. While existing technologies may provide limited functionality for a non-target rank to apply an on-die termination impedance in connection with a received command (e.g., a read or write command for a target rank), non-target ranks typically are unable to perform operations in parallel with an operation performed by a target rank, such as refresh operations. For example, an activate command typically targets a single rank at a time, while non-target ranks remain idle. Examples of setting termination impedance based on encoding bits in a command are described in the Applicant's U.S. Patent App. No. 63/677,969, filed on Jul. 31, 2024, the disclosure of which is incorporated herein by reference for any purpose.

Disclosed herein are systems, apparatuses, and methods for non-target commands. A command is received at multiple memory ranks. A first memory rank may be a target rank for the command, and a second memory rank may be a non-target rank for the command. In some embodiments, the first memory rank performs a first operation responsive to the command and an active pulse of a first chip select signal, while the second memory rank performs a second operation different from the first operation responsive to the command and at least two active pulses of a second chip select signal. In some embodiments, the first memory rank performs the first operation responsive to the command, while the second memory rank performs a second operation different from the first operation responsive to the command, and the second operation is performed based on at least one rank encoding bit in the command. The at least one rank encoding bit can be used to identify a target rank for the command, and one or more other ranks may be identified as a non-target rank based on the at least one rank encoding bit. In some embodiments, the first and second operation may be performed in parallel and/or with the same command timing. The second operation performed by the non-target rank may be, for example, a refresh operation, such as an operation to refresh one or more rows in a non-target rank using address information in the command and/or using an address from a refresh counter of the non-target rank. In some embodiments, the received command may be, for example, an activate command to activate a row in a particular bank of the target rank for a subsequent access operation. Additionally or alternatively, in some embodiments, the received command may be a precharge command or a refresh command. Embodiments of the disclosure are not limited to these example commands.

Advantages of the disclosed technology include, without limitation, improvements related to command bandwidth. For example, multiple functions may be achieved in a single command, which previously would have required multiple commands. In some implementations, functionality that previously required a separate refresh command may be achieved in one or more non-target ranks while a target rank performs an operation responsive to a command, such as an activate, precharge, or refresh command. Moreover, the disclosed technology may reduce noise, as compared to technologies that perform background refresh operations within the same die, by instead performing a refresh operation at a different rank from a target rank.

While some examples described herein relate to an activate command for a target rank, which may also cause a refresh operation at one or more non-target ranks, it will be appreciated that other commands can be used and other non-target operations can be performed in connection with the commands. Generally speaking, any non-target operation can be performed that does not cause conflicts on one or more busses, such as command/address busses or data busses. Moreover, while example implementations include a target rank and a non-target rank, it will be appreciated that more ranks may be used in other implementations, such as a target rank and two or more non-target ranks, which may each perform different non-target operations.

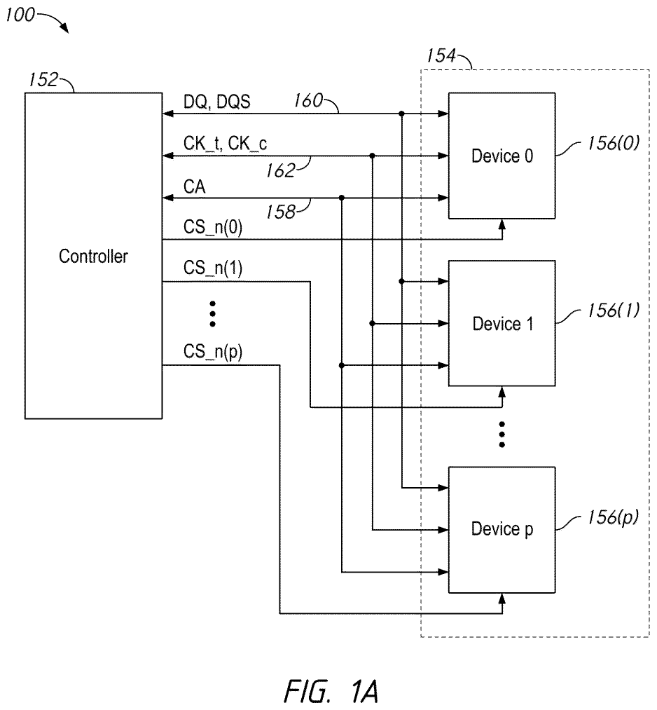

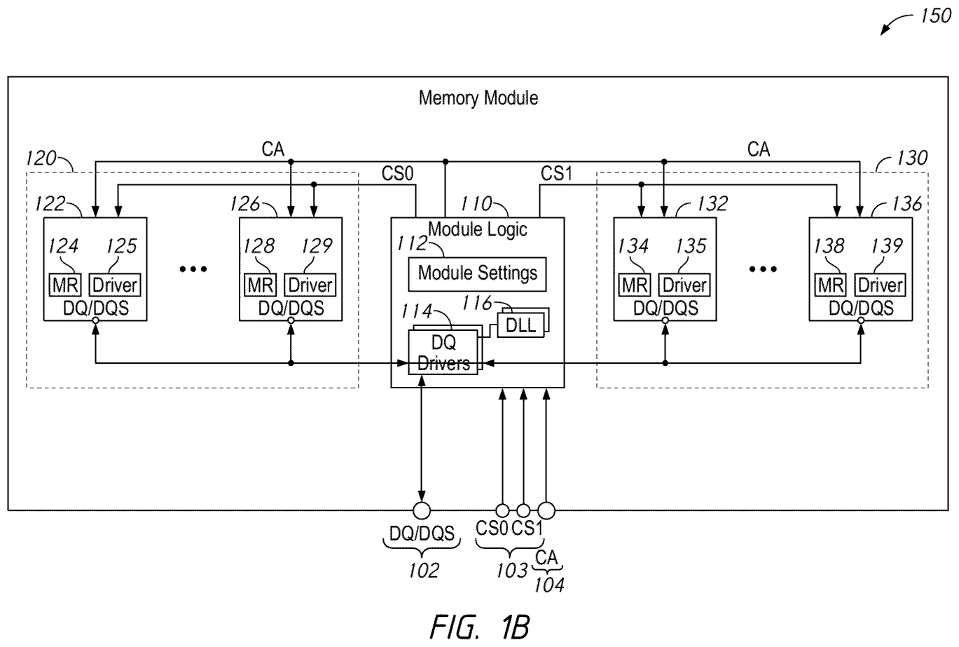

FIG. 1A is a block diagram illustrating a system 100 according to embodiments of the disclosure. The system 100 includes a controller 152 and a memory system 154. In the illustrated embodiment, the memory system 154 includes memory devices 156(0)-156(p) (e.g., “Device 0” through “Device p”), where p is a number greater than one.

In some embodiments, the memory system 154 is a memory module and the memory devices 156(0)-156(p) are included in respective memory ranks. The memory devices 156(0)-156(p) may include a dynamic random access memory (DRAM), a double data rate (DDR) memory, a low power double data rate (LPDDR) memory, a graphics double data rate (GDDR) memory, or other type of memory. Each memory rank can include one or more memory devices (e.g., DRAM devices).

The controller 152 and the memory system 154 are in communication over one or more busses. Commands and addresses (CA) are received by the memory system 154 on a command/address bus 158, and data (DQ) is provided between the controller 152 and the memory system 154 over a data bus 160. Various clocks may be provided between the controller 152 and the memory system 154 over a clock bus 162. The clock bus 162 may include signal lines for providing system clocks CK_t and CK_c received by the memory system 154 and data clocks (strobes) DQS_t and DQS_c received by the memory system 154 and/or provided to the controller 152. Each of the busses may include one or more signal lines on which signals are provided. The memory devices 156(0)-156(p) may each be coupled to the CA bus 158, the DQ bus 160, and/or the clock bus 162. Each memory device 156(0)-156(p) may be coupled to a respective chip select (CS) line CS_n(0)-CS_n(p).

The CK_t and CK_c clocks provided by the controller 152 to the memory system 154 are used for timing the provision and receipt of the commands and addresses. The DQS_t and DQS_c clocks are used for timing provision of data. The CK_t and CK_c clocks are complementary, and the DQS_t and DQS_c clocks are complementary. Clocks are complementary when a rising edge of a first clock occurs at a same time as a falling edge of a second clock, and when a rising edge of the second clock occurs at a same time as a falling edge of the first clock.

The controller 152 provides commands to the memory system 154 to perform memory operations. Examples of memory commands include timing commands for controlling the timing of various operations, explicit power-down entry and exit commands and commands for auto power-down for controlling entry into power-down, access commands for accessing the memory, such as read commands for performing read operations and write commands for performing write operations, refresh commands, activate commands, precharge commands, deselect commands, no-operation commands, as well as other commands. The signals provided by the controller 152 to the memory system 154 further include external control signals (e.g., chip select signals CS_n(0), CS_n(1), CS_n(p)).

The memory devices 156(0)-156(p) are provided the commands, addresses, data, and clocks, and the external control signals. In some embodiments, target memory devices of the memory devices 156(0)-156(p) receive an active pulse of a respective chip select signal CS_n(0), CS_n(1), CS_n(p) for a command, while non-target memory devices of the memory devices 156(0)-156(p) receive at least two active pulses of a respective chip select signal CS_n(0), CS_n(1), CS_n(p) for the command. In some embodiments, rank encoding bits in a command are used to specify target memory devices of the memory devices 156(0)-156(p), and non-target memory devices of the memory devices 156(0)-156(p) may be identified based on the rank encoding bits. Target memory devices (e.g., in a target rank) may perform a first operation responsive to the command, and non-target memory devices (e.g., in a non-target rank) may perform a second operation different from the first operation responsive to the command. For example, the command may be an activate command to activate at least one row of at least one bank in the target rank. Responsive to the activate command, the target memory devices activate the at least one row, while the non-target memory devices perform a different operation, which may be a refresh operation. While example commands and corresponding non-target operations are described herein, it will be appreciated that different commands and non-target operations can be used. In some implementations, multiple ranks may be non-target ranks for the command, and the non-target ranks may be configured to respond in different ways to the command. For example, one non-target rank may perform a refresh operation, while a different non-target rank may remain idle. Additionally or alternatively, one non-target rank may perform a first kind of refresh operation, while a different non-target rank may perform a second kind of refresh operation different from the first kind of operation.

Mode registers included in each of the memory devices 156(0)-156(p) may be programmed with information for setting various operating modes and/or to select features for operation of the memory devices 156(0)-156(p). One of the settings may be for decoding rank encoding bits in a received command. Additionally, one or more settings in the mode registers may be for determining an operation to be performed by a non-target rank responsive to a command.

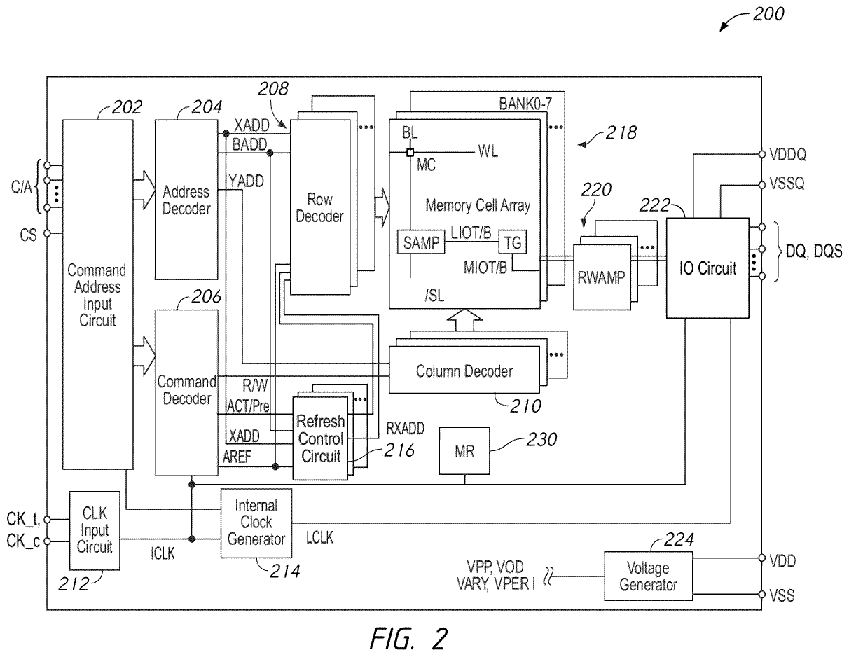

Mode register write commands and mode register read commands can be used to access mode registers in the memory devices 156(0)-156(p) (e.g., mode register 230 in FIG. 2). For example, a mode register write command can be provided by the controller 152 to respective memory devices 156(0)-156(p) to configure each memory device to decode rank encoding bits specifying a target rank for a received command. Additionally, a mode register write command can be provided by the controller 152 to respective memory devices 156(0)-156(p) to configure the memory devices to determine and/or perform an operation when it is included in a non-target rank of a received command (e.g., based on one or more bits in the command and/or based on receiving one or more active pulses of a chip select signal). Such a mode register write command may configure the memory devices to determine whether to perform a target rank operation responsive to a command or a non-target rank operation responsive to the command.

FIG. 1B is a block diagram illustrating a system 150 according to embodiments of the disclosure. The system 150 may be a memory module, which packages together multiple memory devices (e.g., memory dice 122, 126, 132, 136). Each memory device includes a memory array that stores information in memory cells. A controller (not shown) accesses one or more of the memory devices by passing commands and addresses along command and address (CA) terminals 104 and sends and receives data to/from one or more memory devices along external data terminals (DQ/DQS) 102. Additionally, the controller provides one or more chip select (CS) signals along CS terminals (CS0/CS1) 103. In contrast, with the system 100 of FIG. 1A, the system 150 includes module logic 110, which may include a buffer which acts to help routing of command(s), address(es), and/or data between the external terminals of the module (e.g., the CA terminals 104, CS terminals 103, and DQ terminals 102) and the corresponding terminal(s) of the memory devices. For example, each memory device may have CA and DQ terminals, coupled to the external terminals through the module logic 110. The module logic 110 includes output (or DQ) drivers 114 which receive data signals from the accessed memory devices and drive the external terminals 102 based on those internal signals. Additionally, the module logic 110 may receive system clock signals and distribute the system clock signals to the memory devices.

The memory devices on the system 150 may be organized into ranks. For example, the memory system 150 of FIG. 1B includes two ranks 120 and 130. More or fewer ranks per module may be used in other example embodiments. Each rank includes a number of memory devices. For example, the first rank 120 includes at least memory dice 122 and 126, while the second rank 130 includes at least memory dice 132 and 136. For the sake of brevity, only four memory devices (memory dice 122, 126, 132, and 136) are shown. However, more or fewer memory devices per rank may be used in other example embodiments.

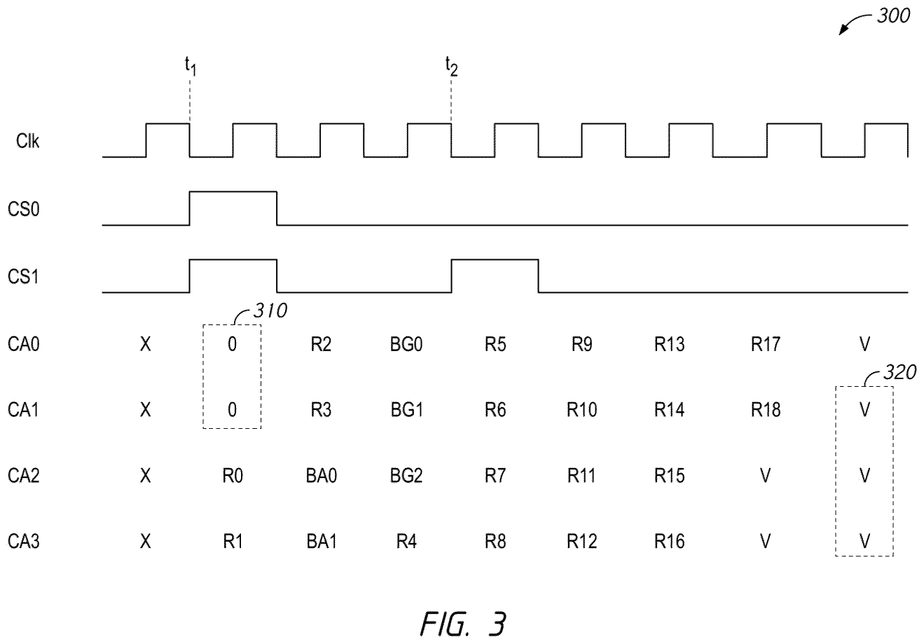

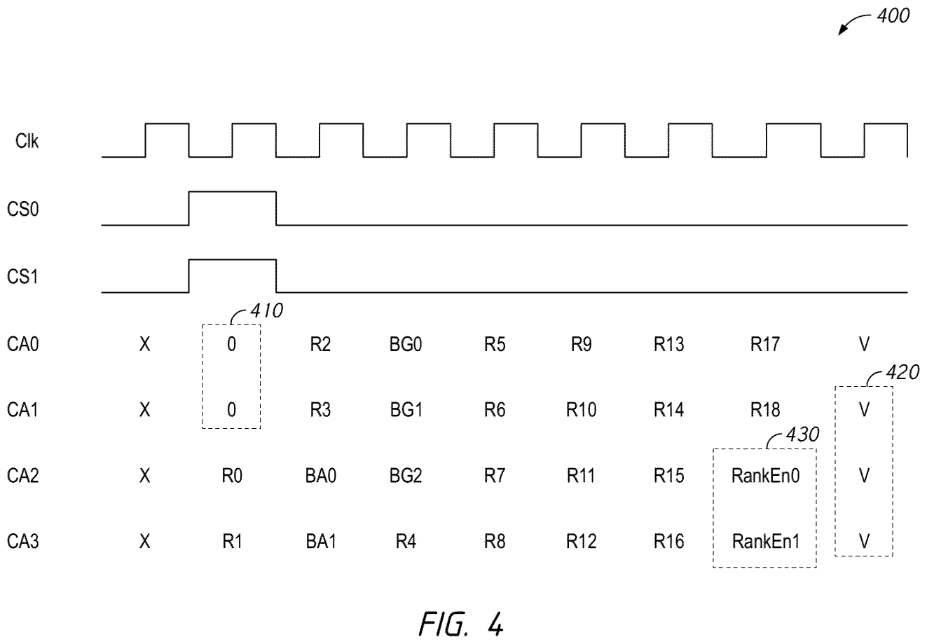

During an example operation, the system 150 receives an activate command along external CA terminals 104. The system 150 also receives a CS signal for the activate command along a CS terminal 103. For example, an active pulse of a first CS signal CS0 for the first rank 120 is received, and at least two active pulses of a second CS signal CS1 are received for the second rank 130. As further discussed with reference to FIG. 3, the active pulses of the respective CS signals may correspond to the first rank 120 being a target rank for the activate command and the second rank 130 being a non-target rank for the activate command. Additionally or alternatively, an active pulse of the first CS signal CS0 for the first rank 120 is received, and an active pulse of the second CS signal CS1 is received for the second rank 130. As further discussed with reference to FIG. 4, rank encoding bits in the activate command may identify which of the first rank 120 and the second rank 130 is a target rank for the activate command and a non-target rank for the activate command. Responsive to the activate command, the target rank for the activate command activates a row in a bank based on address information included in the activate command, while the non-target rank for the activate command performs a non-target operation, such as a refresh operation. In examples where more than two ranks are used, two or more ranks may be non-target ranks for the command, and the non-target ranks may respond in different ways to the command, such as performing different non-target operations and/or remaining idle.

The output driver circuits 114 may contain synchronizer circuits which may synchronize the data to a delayed clock signal provided by a delay circuit 116. The delayed clock signal may mimic a latency of the memory to ensure that read data arrives a specified number of clock cycles after a read command is received. For example, the delay circuit 116 may have an adjustable delay which is matched to the latency. In some embodiments, the delay circuits 116 may be shared by the output circuits 114 associated with a memory. In some embodiments, the delay circuits 116 may be shared between memory devices. For example, the delay circuits 116 may be shared based on distance from the module logic 110 (e.g., shared based on expected latency). For example, memory die 126 and memory die 132 may share a delay circuit 116, and memory die 126 and memory die 132 may share a second delay circuit.

The system 150 includes a set of internal data buses which couple each memory's DQ pads to the module logic 110. The data buses include one or more conductive elements, and the voltage(s) along the data buses represent data being transmitted to/from the memory. For example, a first voltage may represent a high logical level, while a second voltage may represent a low logical level. In some embodiments, other arrangements may be used, for example, multi-level signaling where multiple bits are provided across a single signal line by using more than two voltages to represent the logical states of multiple bits. Similarly, in some embodiments, more data bus lines may be used than there are external terminals associated with that memory. In such embodiments, the output drivers 114 may include decoders to receive the data and split it into the appropriate number of outputs.

The module logic 110 includes a module settings register 112. The module settings register 112 may be a set of programmable registers, which are used to set one or more values for the operation of the system 150. The module settings register 112 may act in a fashion analogous to the mode registers of the memory devices. Each memory device may have a mode register, which includes a number of registers which store values related to the operation of the memory. For example, memory die 122 includes mode register 124, memory die 126 includes mode register 128, memory die 132 includes mode register 134, and memory die 136 includes mode register 138. The module settings register 112 (optionally in conjunction with the mode registers of the memory devices) may work to enable various settings of the memory devices. In various embodiments, settings in the mode register of each memory device can be configured to cause a respective memory device to decode a command and/or one or more chip select signals for the command to perform a target operation or a non-target operation for the command. One or more settings in the mode register of each memory device may also control a non-target operation performed by the memory device when the memory device is included in a non-target rank of a command.

FIG. 2 is a block diagram illustrating a memory device 200 according to embodiments of the disclosure. The memory device 200 may be, for example, a DRAM device integrated on a single semiconductor chip. The memory device 200 may be a die of a memory system, such as one of memory dice 122, 126, 132, and 136 of FIG. 1B or one of memory devices 156(0)-156(p) of FIG. 1A.

The memory device 200 includes a memory array 218. The memory array 218 is shown as including a plurality of memory banks. In the embodiment of FIG. 2, the memory array 218 is shown as including eight memory banks BANK0-BANK7. More or fewer banks may be included in the memory array 218 of other embodiments. For example, memory devices 200 may include 4, 16, or 32 banks. Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 208, and the selection of the bit lines BL is performed by a column decoder 210. In the embodiment of FIG. 2, the row decoder 208 includes a respective row decoder for each memory bank and the column decoder 210 includes a respective column decoder for each memory bank. The bit lines BL are coupled to a respective sense amplifier (SAMP). Read data from the bit line BL is amplified by the sense amplifier SAMP and transferred to read/write amplifiers 220 over complementary local data lines (LIOT/B), transfer gate (TG), and complementary main data lines (MIOT/B). Conversely, write data outputted from the read/write amplifiers 220 is transferred to the sense amplifier SAMP over the complementary main data lines MIOT/B, the transfer gate TG, and the complementary local data lines LIOT/B, and written in the memory cell MC coupled to the bit line BL.

The memory device 200 may employ a plurality of external terminals that include command and address (CA) terminals coupled to a command and address bus to receive commands and addresses, and a CS signal, clock terminals to receive clocks CK and /K, data terminals DQ to provide data, and power supply terminals to receive power supply potentials VDD, VSS, VDDQ, and VSSQ. The external terminals may be coupled to a controller 240, which may operate the memory by providing various signals to the external terminals.

A controller (e.g., 152 of FIG. 1A) provides the clock terminals with external clocks CK and /CK that are provided to an input circuit 212. The external clocks may be complementary. The input circuit 212 generates an internal clock ICLK based on the CK and /CK clocks. The ICLK clock is provided to the command decoder 206 and to an internal clock generator 214. The internal clock generator 214 provides various internal clocks LCLK based on the ICLK clock. The LCLK clocks may be used for timing operation of various internal circuits. The internal data clocks LCLK are provided to the input/output circuit 222 to time operation of circuits included in the input/output circuit 222, for example, to data receivers to time the receipt of write data.

The controller provides the CA terminals with commands and memory addresses. There may be a command/address bus which couples the controller to the CA terminals of the memory device 200. For example, there may be a set of CA terminals or pins, each coupled to a conductive element of the CA bus.

The memory addresses supplied to the CA terminals are transferred, via a command/address input circuit 202, to an address decoder 204. The address decoder 204 receives the address and supplies a decoded row address XADD to the row decoder 208 and supplies a decoded column address YADD to the column decoder 210. The address decoder 204 may also supply a decoded bank address BADD, which may indicate the bank of the memory array 218 containing the decoded row address XADD and column address YADD.

The controller may provide the CA terminals with commands. Examples of commands include timing commands for controlling the timing of various operations, activate commands to active one or more rows for a subsequent access operation, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The command decoder 206 may decode received commands to determine an operation to be performed by the memory device 200, which may be based on whether the memory device 200 is included in a target rank or a non-target rank for the command. As described herein, the command decoder 206 may receive one or more rank encoding bits in the command, and the memory device 200 may be included in a target rank when the one or more rank encoding bits match one or more predetermined bits (e.g., in the mode register 230). Additionally or alternatively, the memory device 200 may be included in a non-target rank when at least two active pulses of the chip select signal CS are received for a command, and the memory device may be included in a target rank when one active pulse of the chip select signal CS is received for the command.

Control commands may be provided as internal command signals to a command decoder 206 via the command/address input circuit 202. The command decoder 206 includes circuits to decode the internal command signals to generate various internal signals and commands for performing operations. For example, the command decoder 206 may provide a row command signal to select a word line and a column command signal to select a bit line. The command decoder 206 also provides activation and precharge signals to the different banks of the memory. An activation signal ACT may indicate that a word line in that bank should be activated, while a precharge signal Pre may indicate that the word lines should be precharged (e.g., closed) in anticipation of a next activation command. In some embodiments, the ACT and Pre signals may share a signal line.

The device 200 may receive commands and addresses as part of an access operation, such as a read operation. As part of the access operation, a row address and bank address are received along with an activate command. As part of the access operation, a column address and bank address are received along with a read command. Responsive to the read operation, read data is read from memory cells in the memory array 218 corresponding to the row address and column address. The commands associated with the read operation are received by the command decoder 206, which provides internal commands so that read data from the memory array 218 is provided to the read/write amplifiers 220. Responsive to the activate command the row decoder 208 activates a word line associated with the row address. While the row is active, memory cells along that row are coupled to sense amplifiers activated by the column decoder 210 responsive to the read command to read data out along the LIOT/B lines. The read data is output to outside from the data terminals DQ via the input/output circuit 222. The command decoder 206 may then provide a precharge command which may ‘close’ the active row.

The device 200 may receive commands and addresses as part of an access operation, such as a write operation. As part of the write operation, a row address and bank address are received along with an activate command and a column address and bank address are received along with write data and a write command. Responsive to the write operation, write data supplied to the data terminals DQ is written to a memory cells in the memory array 218 corresponding to the row address and column address. The commands associated with the write operation are received by the command decoder 206, which provides internal commands so that the write data is received by data receivers in the input/output circuit 222. Responsive to the activate command the row decoder 208 activates a word line associated with the row address. While the row is active, memory cells along that row are coupled to sense amplifiers activated by the column decoder 210 responsive to the write command to receive write data. Write clocks may also be provided to the external clock terminals for timing the receipt of the write data by the data receivers of the input/output circuit 222. The write data is supplied via the input/output circuit 222 to the read/write amplifiers 220, and by the read/write amplifiers 220 to the memory array 218 to be written into the memory cell MC. The command decoder 206 may then provide a precharge command which may ‘close’ the active row.

The device 200 may also perform refresh operations. The refresh operations may be performed as part of an auto-refresh operation, where a controller issues an auto-refresh command or as part of a self-refresh operation, where the memory refreshes itself based on internal commands. The refresh control circuit 216 supplies a refresh row address RXADD to the row decoder 208, which may refresh one or more wordlines WL indicated by the refresh row address RXADD. In some embodiments, the refresh address RXADD may represent a single wordline. In some embodiments, the refresh address RXADD may represent multiple wordlines, which may be refreshed sequentially or simultaneously by the row decoder 208. In some embodiments, the number of wordlines represented by the refresh address RXADD may vary from one refresh address to another. The refresh control circuit 216 may be controlled to change details of the refreshing address RXADD (e.g., how the refresh address is calculated, the timing of the refresh addresses, the number of wordlines represented by the address), or may operate based on internal logic.

The device 200 includes a mode register 230 that may be used to control various settings of the device 200. For example, the mode register 230 may include a setting which is used to decode one or more rank encoding bits in a command specifying a target rank for the command. The controller may provide a mode register write (MRW) command to set values in the mode register 230 used to decode the one or more rank encoding bits, such that the device 200 performs a target operation when the one or more rank encoding bits specify that a rank including the device 200 is a target rank or a non-target operation when the one or more rank encoding bits do not specify that the rank including the device 200 is the target rank. The settings may include one or more mode register bits that are used by the command decoder 206 to evaluate received rank encoding bits in a command to determine a match when the memory device 200 is included a target rank for the command. The mode register 230 includes a number of registers, each of which may store one or more bits which correspond to a setting or piece of information about the device 200.

In an example implementation, the memory device 200 receives an activate command and one or more active pulses of a chip select signal CS for the activate command. When the memory device 200 is determined to be in a target rank, based on one or more rank encoding bits in the command or based on receiving one active pulse of the chip select signal CS for the command, the memory device 200 performs an operation to activate a specified wordline WL identified using the row decoder 208 for a subsequent access operation. When the memory device 200 is not determined to be in the target rank and/or is determined to be in a non-target rank, based on the one or more rank encoding bits in the command or based on receiving at least two active pulses of the chip select signal CS for the command, the memory device performs a non-target operation, which may be a refresh operation. For example, the refresh control circuit 216 may select one or more wordlines WL to refresh using a refresh counter and/or using address information in the command, and the refresh control circuit 216 may cause the one or more wordlines WL to be refreshed. The memory device 200 may perform the non-target operation in parallel with performance of an operation performed by a target rank, or vice versa. For example, the memory device 200 may perform a refresh operation when it is included in the non-target rank while a different memory device 200 included in the target rank performs an operation to activate a word line responsive to an activate command.

The power supply terminals are supplied with power supply potentials VDD and VSS. The power supply potentials VDD and VSS are supplied to an internal voltage generator circuit 224. The internal voltage generator circuit 224 generates various internal potentials VPP, VOD, VARY, VPERI, and the like based on the power supply potentials VDD and VSS supplied to the power supply terminals. The internal potential VPP is mainly used in the row decoder 208, the internal potentials VOD and VARY are mainly used in the sense amplifiers SAMP included in the memory array 218, and the internal potential VPERI is used in many peripheral circuit blocks.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals, or the power supply potentials VDDQ and VSSQ supplied to the power supply terminals may be different potentials from the power supply potentials VDD and VSS supplied to the power supply terminals. The power supply potentials VDDQ and VSSQ supplied to the power supply terminals may be used for the input/output circuit 222 so that power supply noise generated by the input/output circuit 222 does not propagate to the other circuit blocks.

FIG. 3 is a diagram 300 illustrating an activate command according to embodiments of the disclosure. The activate command of FIG. 3 is received by multiple ranks of a memory system. For example, at least a first memory rank and a second memory rank may receive the illustrated activate command. The ranks of the memory system may include one or more memory devices (e.g., multiple devices 200 of FIG. 2). The activate command is provided by a controller (e.g., 152 of FIG. 1A) to cause a target rank to perform an operation to activate a row for a subsequent access operation.

Multiple cycles of a clock signal Clk for the activate command are received. The clock signal Clk may be one of the system clocks CK_t or CK_c, and/or a clock signal based on the system clocks CK_t and/or CK_c. The first memory rank receives an active pulse of a first chip select signal CS0 at a time t₁. The second memory rank receives a first active pulse of a second chip select signal CS1 at the first time t₁ and a second active pulse of the second chip select signal CS1 at a second time t₂.

Respective command decoders of the first and second memory ranks (e.g., 206 of FIG. 2) may decode the active pulses of the chip select signals CS0 and CS1. For example, the second memory rank is indicated as a non-target rank based on the first and second active pulses of the second chip select signal CS1 for the command, while the first memory rank is indicated as a target rank based on the active pulse of the first chip select signal CS0 for the command.

The command is received at command/address pins CA0-CA3 as bits having respective logic levels at different cycles of the clock signal Clk. For example, the command may be received within 8 cycles of the clock signal Clk. While four command/address pins are illustrated, it will be appreciated that more or fewer command/address pins may be used. Bits 310 in the command identify the command as an activate command. While the command may be received within 8 clock cycles of the clock signal Clk, it will be appreciated that in other embodiments the command may be received within more or fewer clock cycles. The command may include various information, such as row address information, bank address information, and bank group information.

The activate command may cause the target memory rank, which receives the active pulse of the first chip select signal CS0, to perform an operation to activate a row identified using address information in the command for a subsequent access operation. Additionally, responsive to the activate command, one or more non-target memory ranks, which receive the two active pulses of the second chip select signal CS1, may perform a different operation, such as a refresh operation. The operation performed by the one or more non-target memory ranks may be performed based on one or more settings in a mode register of the non-target memory rank, such as a setting specifying a non-target operation. Additionally or alternatively, the different operation may use information in the command. For example, a non-target memory rank may perform a refresh operation on one or more rows and/or banks identified in the command. In some implementations, the non-target memory rank performs a full refresh operation of a bank identified using a bank address of the command. Additionally or alternatively, the command may include one or more non-target command bits 320, which may provide information regarding a non-target operation to be performed by a non-target memory rank. The non-target command bits 320 may be decoded by a command decoder of the non-target rank and/or using one or more settings in a mode register of the non-target rank to determine a non-target operation to perform.

In various embodiments, the non-target memory rank performs a refresh operation. Examples of a refresh operation include all-bank refresh (REFab), per-bank refresh (REFpb), double-bank refresh (REFdb), and same-bank refresh (REFsb). The refresh operation may use information in the received command, such as a row address and/or a bank address, to perform the refresh operation. Additionally or alternatively, the refresh operation may use a counter in a refresh control circuit to identify one or more rows to refresh (e.g., 216 of FIG. 2). The refresh operation may be to refresh one row or multiple rows. A refresh mode corresponding to a type of refresh that is performed may be selectable using a mode register.

When a protocol with explicit precharge commands is used, the activate command may be followed by a precharge command provided to the first memory rank and the second memory rank to close the addressed row (e.g., after performance of an access operation) and the one or more rows refreshed in the non-target rank. When a protocol with read or write autoprecharge is used, the precharge timing for the non-target rank may be controlled by one or more circuits in the non-target rank.

While the diagram 300 illustrates a command received by at least first and second ranks, which receive respective chip select signals CS0 and CS1, more than two ranks may be used in some embodiments. For example, a third rank may be an additional non-target rank that receives at least two pulses of a respective chip select signal (not shown), and the third rank may perform a different non-target operation.

FIG. 4 is a diagram 400 illustrating an activate command according to embodiments of the disclosure. The activate command of FIG. 4 is received by multiple ranks of a memory system. For example, at least a first memory rank and a second memory rank may receive the illustrated activate command. The ranks of the memory system may include one or more memory devices (e.g., multiple devices 200 of FIG. 2). The activate command is provided by a controller (e.g., 152 of FIG. 1A) to cause a target rank to perform an operation to activate a row for a subsequent access operation.

Multiple cycles of a clock signal Clk for the activate command are received. The clock signal Clk may be one of the system clocks CK_t or CK_c, and/or a clock signal based on the system clocks CK_t and/or CK_c. The first memory rank receives an active pulse of a first chip select signal CS0. The second memory rank receives an active pulse of a second chip select signal CS1.

The command is received at command/address pins CA0-CA3 as bits having respective logic levels at different cycles of the clock signal Clk. Bits 410 in the command identify the command as an activate command. The command may include various information, such as row address information, bank address information, and bank group information. Additionally, the command includes rank encoding bits 430, which specify a target rank of the command. For example, a setting in a respective mode register of the first memory rank and the second memory rank may specify a set of bits that, when matched with the rank encoding bits 430, causes the respective rank to perform a target operation. When the rank encoding bits 430 do not match bits stored in the respective mode register, the respective rank is a non-target rank for the command. Respective command decoders of the first and second memory ranks (e.g., 206 of FIG. 2) may decode the rank encoding bits 430 to perform a target operation or a non-target operation.

The activate command may cause the target memory rank to perform an operation to activate a row identified using address information in the command for a subsequent access operation. Additionally, responsive to the activate command, the non-target memory rank may perform a different operation, such as a refresh operation. The operation performed by the non-target memory rank may be performed based on one or more settings in a mode register of the non-target memory rank, such as a setting specifying a non-target operation. Additionally or alternatively, the operation performed by the non-target memory rank may use information in the command. For example, the non-target memory rank may perform a refresh operation on one or more rows and/or banks identified in the command. In some implementations, the non-target memory rank performs a full refresh operation of a bank identified using a bank address of the command. Additionally or alternatively, the command may include one or more non-target command bits 420, which may provide information regarding a non-target operation to be performed by the non-target memory rank. The non-target command bits 420 may be decoded by a command decoder of the non-target rank and/or using one or more settings in a mode register of the non-target rank to determine a non-target operation to perform.

In various embodiments, the non-target memory rank performs a refresh operation. Examples of a refresh operation include all-bank refresh (REFab), per-bank refresh (REFpb), double-bank refresh (REFdb), and same-bank refresh (REFsb). The refresh operation may use information in the received command, such as a row address and/or a bank address, to perform the refresh operation. Additionally or alternatively, the refresh operation may use a counter in a refresh control circuit to identify one or more rows to refresh (e.g., 216 of FIG. 2). The refresh operation may be to refresh one row or multiple rows. A refresh mode corresponding to a type of refresh that is performed may be selectable using a mode register.

When a protocol with explicit precharge commands is used, the activate command may be followed by a precharge command provided to the first memory rank and the second memory rank to close the addressed row (e.g., after performance of an access operation) and the one or more rows refreshed in the non-target rank. When a protocol with read or write autoprecharge is used, the precharge timing for the non-target rank may be controlled by one or more circuits in the non-target rank.

While the diagram 400 illustrates a command received by at least first and second ranks, which receive respective chip select signals CS0 and CS1, more than two ranks may be used in some embodiments. For example, a third rank may be an additional non-target rank that receives a respective chip select signal (not shown) and decodes the rank encoding bits 430, and the third rank may perform a different non-target operation when the third rank is a non-target rank for the command.

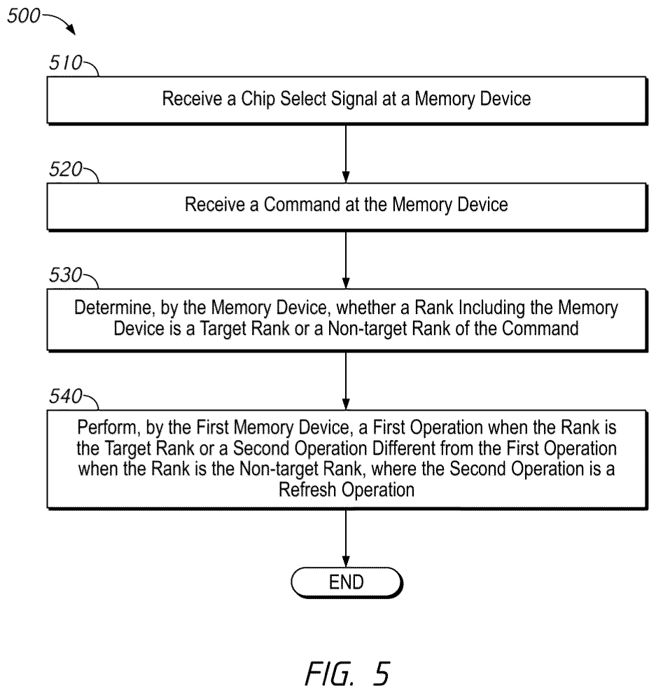

FIG. 5 is a flow diagram illustrating a process 500 for an operation performed by a memory device responsive to a command according to embodiments of the disclosure. The process 500 may be performed using a memory device and/or a memory rank, such as the memory device 200 of FIG. 2. The memory device and/or memory rank that performs the process 500 may be included in a memory system (e.g., a memory module), such as the system 100 of FIG. 1A or the system 150 of FIG. 1B. The command used in the process 500 may correspond to the command illustrated with reference to the diagram 300 of FIG. 3 or the diagram 400 of FIG. 4.

The process 500 begins at block 510, where a chip select signal is received at a memory device. The chip select signal may be received from a controller (e.g., 152 of FIG. 1A). In various embodiments, one or more active pulses of the chip select signal are received. The memory device is included in a rank, which may be a target rank or a non-target rank for a command.

The process 500 proceeds to block 520, where a command is received at the memory device. The command may be received from the memory controller. The command may be, for example, an activate command to cause a target rank to activate a row for a subsequent access operation. Additionally or alternatively, the command may be a precharge command or a refresh command.

The process 500 proceeds to block 530, where the memory device determines whether a rank that includes the memory device is a target rank or a non-target rank for the command. In some embodiments, the memory device determines that it is included in the target rank or the non-target rank based on a number of active pulses of the chip select signal for the command (e.g., as described with reference to the diagram 300 of FIG. 3). For example, the memory device may determine that it is included in the non-target rank when two active pulses of the chip select signal are detected for the command, and the memory device may determine that it is included in the target rank when one active pulse of the chip select signal is detected for the command. In some embodiments, the memory device (e.g., using a command decoder, such as 206 of FIG. 2) determines whether it is included in the target rank or the non-target rank based on one or more rank encoding bits in the command such as the rank encoding bits 430 of FIG. 4. For example, the memory device may determine that it is included in the target rank when at least one rank encoding bit has a predetermined value, such as a value stored in a mode register of the memory device, and the memory device may determine that it is included in the non-target rank when the at least one rank encoding bit does not have the predetermined value.

The process 500 proceeds to block 540, where the memory device performs a first operation when the rank that includes the memory device is the target rank or a second operation different from the first operation when the rank that includes the memory device is the non-target rank, where the second operation is a refresh operation. For example, when the memory device is included in the target rank and the command is an activate command, the memory device performs an operation to activate a specified wordline for a subsequent access operation. When the memory device is included in the non-target rank, the memory device performs the second operation, which is the refresh operation. The refresh operation may include, for example, all-bank refresh (REFab), per-bank refresh (REFpb), double-bank refresh (REFdb), or same-bank refresh (REFsb). The refresh operation may refresh one row or multiple rows. The first operation may be a target operation, and the second operation may be a non-target operation.

The operation performed by the non-target rank may be determined in various ways. For example, a setting in a mode register of the memory device may specify a non-target operation to be performed by the memory device when the memory device is included in a non-target rank for a command (e.g., an activate command). Additionally or alternatively, a command decoder of the memory device may be configured to determine an operation to perform based on one or more bits in the command, such as the bits 320 of FIG. 3 or the bits 420 of FIG. 4. In these and other implementations, the non-target operation may use information included in the command, such as address information. For example, when an activate operation is performed at a target rank, a non-target rank may perform a refresh operation at a corresponding bank and/or row identified in the command. Additionally or alternatively, the non-target operation may refresh one or more rows based on an address received from a refresh counter.

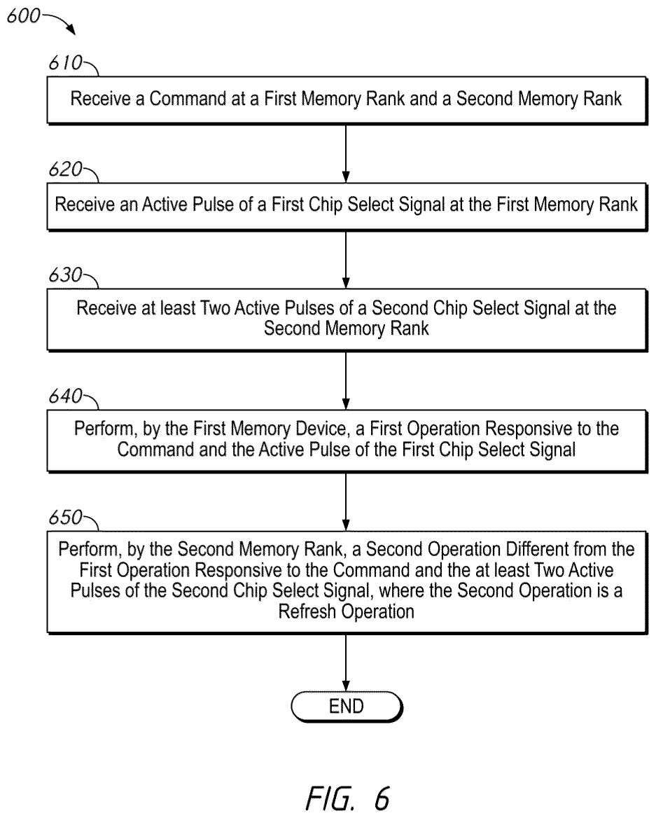

FIG. 6 is a flow diagram illustrating a process 600 for operations performed by memory ranks responsive to a command according to embodiments of the disclosure. The process 600 may be performed using memory devices and/or memory ranks, such as memory device 200 of FIG. 2. The memory devices and/or memory ranks that perform the process 600 may be included in a memory system (e.g., a memory module), such as the system 100 of FIG. 1A or the system 150 of FIG. 1B. The command used in the process 600 may correspond to the command illustrated with reference to the diagram 300 of FIG. 3.

The process 600 begins at block 610, where a command is received at a first memory rank and a second memory rank. As discussed herein, the command may be, for example, an activate command, a precharge command, or a refresh command.

The process 600 proceeds to block 620, where an active pulse of a first chip select signal is received at the first memory rank.

The process 600 proceeds to block 630, where at least two active pulses of a second chip select signal are received at the second memory rank.

The process 600 proceeds to block 640, where the first memory rank performs a first operation responsive to the command and the active pulse of the first chip select signal. As described with reference to FIG. 3, the first rank may be a target rank of the command when one active pulse of the first chip select signal is received for the command. The first memory rank may perform an operation corresponding to the command when it is the target rank. For example, when the command is an activate command, the first rank will activate a specified row for a subsequent access operation.

The process 600 proceeds to block 650, where the second memory rank performs a second operation different from the first operation responsive to the command and the at least two active pulses of the second chip select signal. As described with reference to FIG. 3, the second rank may be a non-target rank of the command when the at least two active pulses of the second chip select signal are received for the command. In some embodiments, the second operation is a refresh operation. The refresh operation may include, for example, all-bank refresh (REFab), per-bank refresh (REFpb), double-bank refresh (REFdb), or same-bank refresh (REFsb). The refresh operation may refresh one row or multiple rows.

The second operation may be determined in various ways. For example, a setting in a mode register of the memory rank may specify a non-target operation to be performed by the memory rank when the memory rank is a non-target rank for a command. Additionally or alternatively, a command decoder of the memory device may be configured to determine an operation to perform based on one or more bits in the command, such as the bits 320 of FIG. 3. In these and other implementations, the non-target operation may use information included in the command, such as address information. For example, when an activate operation is performed at a target rank, a non-target rank may perform a refresh operation at a corresponding bank and/or row identified in the command. Additionally or alternatively, the non-target operation may refresh one or more rows based on an address received from a refresh counter.

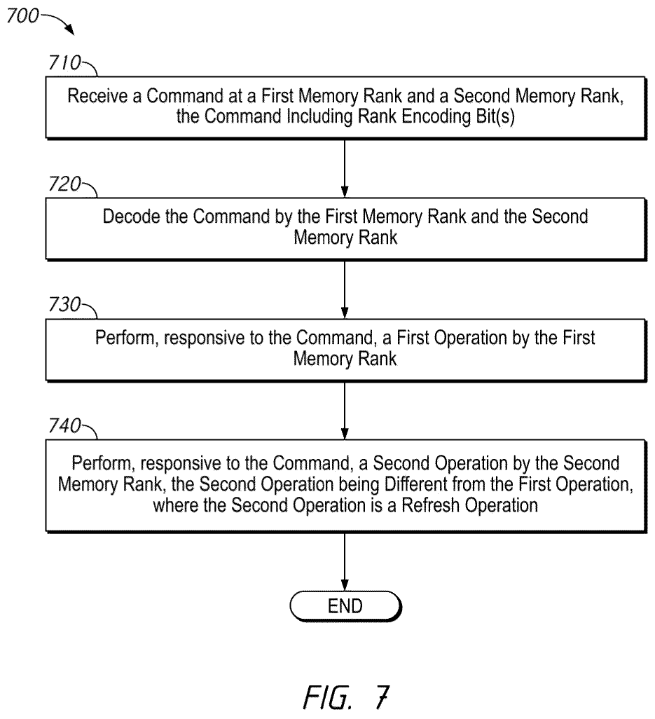

FIG. 7 is a flow diagram illustrating a process 700 for operations performed by memory ranks responsive to a command according to embodiments of the disclosure. The process 700 may be performed using a memory device and/or a memory rank, such as the memory device 200 of FIG. 2. The memory device and/or memory rank that performs the process 700 may be included in a memory system (e.g., a memory module), such as the system 100 of FIG. 1A or the system 150 of FIG. 1B. The command used in the process 700 may correspond to the command illustrated with reference to the diagram 400 of FIG. 4.

The process 700 begins at block 710, where a command is received at a first memory rank and a second memory rank. As described herein, the command may be, for example, an activate command, a precharge command, or a refresh command. The command received at block 710 includes one or more rank encoding bits, such as the bits 430 of FIG. 4.

The process 700 proceeds to block 720, where the received command is decoded by the first memory rank and the second memory rank. For example, a respective command decoder of the first memory rank and the second memory rank may decode the command to determine a type of the command, and further to determine whether the respective memory rank is a target rank or a non-target rank of the command. The determination of whether the respective memory rank is the target rank or the non-target rank is based on the one or more rank encoding bits specifying the target rank for the command. For example, the command decoder may determine whether the one or more rank encoding bits in the command match one or more predetermined rank encoding bits (e.g., in a mode register of the memory rank).

The process 700 proceeds to block 730, where the first memory rank performs a first operation responsive to the command. For example, when the first memory rank is the target rank and the command is an activate command, the first memory rank performs an operation to activate a row specified in the command for a subsequent access operation.

The process 700 proceeds to block 740, where the second memory rank performs a second operation different from the first operation responsive to the command, where the second operation is a refresh operation. The refresh operation may include, for example, all-bank refresh (REFab), per-bank refresh (REFpb), double-bank refresh (REFdb), or same-bank refresh (REFsb). The refresh operation may refresh one row or multiple rows.

The second operation may be determined in various ways. For example, a setting in a mode register of the memory rank may specify a non-target operation to be performed by the memory rank when it is a non-target rank for a command. Additionally or alternatively, a command decoder of the memory device may be configured to determine an operation to perform based on one or more bits in the command, such as the bits 420 of FIG. 4. In these and other implementations, the non-target operation may use information included in the command, such as address information. For example, when an activate operation is performed at a target rank, a non-target rank may perform a refresh operation at a corresponding bank and/or row identified in the command. Additionally or alternatively, the non-target operation may refresh one or more rows based on an address received from a refresh counter.

It will be appreciated that operations may be added to or removed from the processes 500-700 while maintaining a similar functionality. For example, processes 600 and 700 may be modified to include operations performed by multiple non-target ranks for a command, such as a first non-target rank that performs a first non-target operation and a second non-target rank that remains idle or performs a second non-target operation different from the first non-target operation. Additionally, operations in the processes 500-700 may be repeated and/or performed in parallel while maintaining a similar functionality.

While example commands and corresponding non-target operations are described herein, it will be appreciated that different commands and non-target operations may be used in other implementations. Additionally, different non-target operations may be configured for respective commands. For example, a first non-target operation can be performed for a non-target activate command, and a second non-target operation different from the first non-target operation can be performed for a non-target precharge command or a non-target refresh command. Moreover, while examples described herein may refer to two memory ranks, more memory ranks may be used in other implementations. For example, a target rank may perform a first operation responsive to a command, while a first non-target rank performs a second operation different from the first operation responsive to the command and a second non-target rank performs a third operation different from the first operation and the second operation responsive to the command. A person skilled in the art will appreciate that any number of ranks may be used.

While examples of a non-target operation have been described as a refresh operation, it will be appreciated that other non-target operations may additionally or alternatively be implemented. For example, a non-target operation performed by a non-target rank may include one or more of termination impedance (ZQ) calibration start, ZQ calibration latch, data strobe (DQS) oscillator start, DQS oscillator stop, manual error check and scrub (ECS), refresh management (RFM), precharge, or power down entry. Embodiments of the disclosure are not limited to the particular example non-target operations described.

It is to be appreciated that any one of the examples, embodiments, and/or processes described herein may be combined with one or more other examples, embodiments, and/or processes, or be separated and/or performed amongst separate devices or device portions in accordance with the present systems, apparatuses, and methods.

Finally, the above discussion is intended to be merely illustrative of the present technology and should not be construed as limiting the appended claims to any particular embodiment or group of embodiments. Thus, while the present systems, apparatuses, and methods have been described in particular detail with reference to example embodiments, it will be appreciated that modifications and alternative embodiments may be devised by those having ordinary skill in the art without departing from the broader and intended spirit and scope of the present technology as set forth in the claims that follow. Accordingly, the present disclosure is to be regarded in an illustrative manner and is not intended to limit the scope of the appended claims.

What is claimed is:

1. A system comprising:
a first memory rank;
a second memory rank; and
a controller configured to:
provide a first chip select signal to the first memory rank;
provide a second chip select signal to the second memory rank; and
provide a command and an active pulse of the first chip select signal to the first memory rank to cause a target operation to be performed, and provide the command and at least two active pulses of the second chip select signal to the second memory rank to cause a refresh operation to be performed.

2. The system of claim 1, wherein the command comprises an activate command, a precharge command, or a refresh command.

3. The system of claim 1, wherein the first memory rank is configured to determine whether the first memory rank is a target memory rank based on the active pulse of the first chip select signal and the second memory rank is configured to determine whether the second memory rank is the target rank based on the active pulses of the second chip select signal.

4. The system of claim 1, wherein the first memory rank and the second memory rank are configured to perform the respective target operation and refresh operation in parallel.

5. The system of claim 1, wherein the second memory rank comprises a refresh control circuit configured to cause the refresh operation using a row address received from a refresh counter.

6. The system of claim 1, wherein the target operation comprises an operation to activate a row for a subsequent access operation.

7. The system of claim 1, wherein the refresh operation comprises a full refresh of a bank identified using a bank address of the command.

8. The system of claim 1, wherein the second memory rank is configured to perform the refresh operation based on at least one bit in the command or a setting in a mode register of the second memory rank.

9. A method comprising:
receiving, at a memory device and from a memory controller, a chip select signal;
receiving, at the memory device and from the memory controller, a command;
determining, by the memory device, that a rank including the memory device is a non-target rank for the command; and
performing, by the memory device, a refresh operation responsive to determining that the rank of the memory device is the non-target for the command.

10. The method of claim 9, wherein the memory device is configured to determine that the rank including the memory device is the non-target rank based on at least one rank encoding bit in the command.

11. The method of claim 9, wherein the memory device is configured to determine that the rank including the memory device is the non-target rank based on detecting multiple active pulses of the chip select signal for the command.

12. The method of claim 9, wherein the command comprises an activate command, a precharge command, or a refresh command.

13. The method of claim 9, wherein the refresh operation refreshes a row identified using a row address received from a refresh counter.

14. The method of claim 9, wherein the command is configured to cause performance of an operation to activate a row for a subsequent access operation by a target rank.

15. The method of claim 9, wherein the refresh operation comprises a full refresh of a bank identified using a bank address of the command.

16. The method of claim 9, further comprising:
determining, by the memory device, the operation based on at least one bit in the command or a setting in a mode register of the memory device.

17. An apparatus comprising:
a memory device comprising a command decoder configured to:
receive, from a memory controller, a command;
receive, from the memory controller, a chip select signal;
determine that the memory device is included in a non-target rank for the command; and
cause the memory device to perform a refresh operation responsive to the determination that the memory device is included in the non-target rank for the command.

18. The apparatus of claim 17, wherein the command decoder is configured to determine that the memory device is included in the non-target rank based on at least one rank encoding bit in the command received from the memory controller.

19. The apparatus of claim 17, wherein the command decoder is configured to determine that the memory device is included in the non-target rank based on detecting multiple active pulses of the chip select signal for the command.

20. The apparatus of claim 17, wherein the command comprises an activate command, a precharge command, or a refresh command.

21. The apparatus of claim 17, wherein the memory device further comprises a refresh control circuit configured to perform the refresh operation using a row address received from a refresh counter.

22. The apparatus of claim 17, wherein the refresh operation comprises a full refresh of a bank identified using a bank address of the command.

23. A system comprising:
a first memory rank configured to perform a first operation responsive to a command, wherein the command includes at least one rank encoding bit identifying the first memory rank as a target rank for the command;
a second memory rank configured to perform a second operation different from the first operation responsive to the command, the second operation comprising a refresh operation, wherein the second memory rank is identified as a non-target rank for the command based on the at least one rank encoding bit; and
a controller configured to provide the command to the first memory rank and the second memory rank, and further configured to provide an active pulse of a first chip select signal to the first memory rank and an active pulse of a second chip select signal to the second memory rank.

24. The system of claim 23, wherein the refresh operation includes refreshing one or more rows using an address received from a refresh counter of the second memory rank or using address information included in the command.

25. An apparatus comprising:
a memory controller configured to provide a command to a first memory rank and a second memory rank, wherein the command includes at least one rank encoding bit configured to identify the first memory rank as a target rank for the command, and wherein the command is configured to cause the first memory rank to perform a target operation and to cause the second memory rank to perform a non-target operation different from the target operation, the non-target operation comprising a refresh operation.

26. The apparatus of claim 25, wherein the refresh operation includes refreshing one or more rows using an address received from a refresh counter of the second memory rank or using address information included in the command.

27. An apparatus comprising:
a memory controller configured to:
provide an active pulse of a first chip select signal to a first memory rank;
provide at least two active pulses of a second chip select signal to a second memory rank; and
provide a command to the first memory rank and the second memory rank, wherein the command is configured to cause the first memory rank to perform a first operation and to cause the second memory rank to perform a second operation different from the first operation, the second operation comprising a refresh operation.

28. The apparatus of claim 27, wherein the refresh operation includes refreshing one or more rows using an address received from a refresh counter of the second memory rank or using address information included in the command.
